(19) United States
(12) Patent Application Publication
(10) Pub. No.: US 2007/0279871 A1
(43) Pub. Date: Dec. 6, 2007

(54) ELECTRICAL CONNECTION BOX

(75) Inventors: Yuichi ISHIDA, Kakegawa-shi (JP); Masaaki ISHIGURO, Kakegawa-shi (JP); Kazuaki Nakamura, Kakegawa-shi (JP)

Correspondence Address: SUGHRUE-265550, 2100 PENNSYLVANIA AVE. NW, WASHINGTON, DC, 20037-3213, US

(73) Assignee: YAZAKI CORPORATION, Tokyo (JP)

(21) Appl. No.: 11/755,379

(22) Filed: May 30, 2007

(30) Foreign Application Priority Data
May 30, 2006 (JP) P2006-149982

(51) Int. Cl. H05K 7/20

(52) U.S. Cl. 361/704

(57) ABSTRACT

A circuit board includes a plate-shaped conductive core and an insulative section covering the core. An electrical component is disposed on the insulative section. A heat radiating member is disposed on the insulative section and connected to the core. A casing houses the circuit board, the electrical component and the heat generating member.

### BACKGROUND

The present invention relates to an electrical connection box for housing a circuit board on which electrical circuits such as power supply circuits are mounted.

In general, circuit boards including electrical circuits such as power supply circuits are installed in the vehicles with boxes housing the circuit boards. In a case where the circuit board includes a large-current electrical circuit such as a power supply circuit generating large amount of heat, the radiation performance of the box should be enough large.

As a countermeasure for radiating the heat produced from the electrical circuits, the electrical connection box having a cooling structure is well known in the art (for example, see Japanese Patent Publication No. 2001-19838A).

As shown in FIG. 6, in such an electrical connection box, a plurality of print boards 2 having a metal core is contained within the chassis made up of a plurality of casings 1. In addition, such electrical connection box has a structure that heat pipes 6 are connected to a body panel of vehicle to radiate heat from the chassis, in which while heat-conductive insulating sheets 3 and metal spacers 4 are interposed, a radiation fin 5 is attached to the print board 2, and while the heat-conductive insulating sheet 3 is interposed, the heat pipes 6 are attached to the print board 2.

However, the above electrical connection box, in order to radiate heat to the exterior of the chassis, it is necessary to connect the heat pipe 6 to the body panel, and therefore the attaching position in the vehicle is limited.

Further, since the heat-conductive insulating sheet 31 the radiation fin 5 having a complex shape, and the heat pipes 6 are needed for the radiation structure, it becomes large. Hence, it leads to large electrical connection box with higher cost.

Furthermore, when the electrical connection box is dismantled, the heat-conductive insulating sheets 3, the radiation fin 5, and the heat pipes 6 should be detached from the boards 2. As a result it requires a much effort for the dismantling.

### SUMMARY

It is therefore one advantageous aspect of the invention to provide, at low cost, an electrical connection box having not only superior soaking and radiation performance but also superior recycling efficiency, and capable of reducing in size and weight without limiting the attaching position.

According to one aspect of the invention, there is provided an electrical connection box, comprising:

a circuit board, including a plate-shaped conductive core and an insulative section covering the core;

an electrical component, disposed on the insulative section;

a heat radiating member, disposed on the insulative section and connected to the core; and

a casing, housing the circuit board, the electrical component and the heat generating member.

With this configuration, heat transferred from the electrical component to the metal core can be effectively radiated from the heat radiating member. As a result, because the heat-conductive insulating sheet, the radiation fin or the heat pipe are not necessary, it allows supplying large current into the circuit board without using bus bar. Further, due to the simplification of the structure, it allows reduction in size and weight, and cost-saving. It also permits easy dismantlement, without limiting the attaching position. Therefore, the soaking and radiation performance can be much improved.

The heat radiating member may be disposed in the vicinity of the electrical component.

In this case, the heat of the electrical component can be smoothly radiated.

The heat radiating member may abut against an inner face of the casing.

In this case, since the heat radiating member can serve as a member that supports the circuit board with respect to the casing the number of the component can be much reduced and thus simpler structure can be obtained, as compared to a case where a supporting member is separately provided.

### BRIEF DESCRIPTION OF THE DRAWINGS

FIG. 1 is a perspective view of an electrical connection box according to a first embodiment of the invention, showing a disassembled state.

FIG. 2 is an enlarged section view of a part of a circuit board in the electrical connection box of FIG. 1.

FIG. 3 is a perspective view of an electrical connection box according to a second embodiment of the invention, showing a disassembled state.

FIG. 4 is a perspective view of a circuit board and radiation pins in the electrical connection box of FIG. 3.

FIG. 5 is an enlarged section view of a part of the circuit board of FIG. 4.

FIG. 6 is a perspective view of a conventional electrical connection box, showing a disassembled state.

### DETAILED DESCRIPTION OF EXEMPLARY EMBODIMENTS

Exemplary embodiments of the invention will be described below in detail with reference to the accompanying drawings.

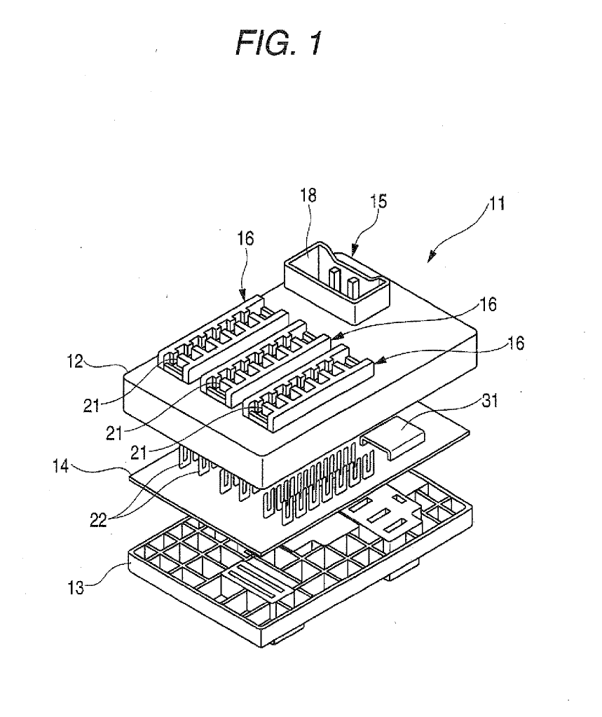

As shown in FIG. 1, an electrical connection box 11 according to a first embodiment of the invention has an upper casing 12 and a lower casing 13. The circuit board 14 is disposed between the upper casing 12 and the lower casing 13. The circuit board 14 Is covered with the upper casing 12 and, the lower casing 13. The wiring pattern (not shown) is formed on the both sides of the circuit board 14. For example, the electrical components (not shown), such as relays, fuses, electronic control units are mounted on the circuit board 14.

The upper casing 12 and the lower casing 13 are formed by, for example, polypropylene that the glass fiber is incorporated into. The upper casing 12 and the lower casing 13 are combined, in a state that the circuit board 14 is sandwiched therebetween.

The electrical connection box 11 has a plurality of socket 15 adapted to be connected with connectors of the wiring harness.

The socket 15 has an engaging concave portion 18 formed in the upper casing 12. The connection terminal is arranged within the engaging concave portion 18, which is uprightly formed so as to electrically connect to the wiring pattern of the circuit board 14. In addition, in the socket 15, the connector of the wiring harness is engaged with the engaging concave portion 18, and then the terminal of the connector is electrically connected to the connection terminal of the socket 15.

Additionally, the electrical connection box 11 has a plurality of sockets 16 capable of attaching the electrical component, such as an external relay.

These sockets 16 have an engaging concave portion 21 formed in the upper casing 12. The connecting terminal 22 is arranged within the engaging concave portion 21, which is uprightly formed so as to electrically connect to the wiring pattern of the circuit board 14. In addition, in the socket 16, the electrical component is engaged with the engaging concave portion 21, and then the connection terminal of the electrical component is electrically connected to the connection terminal 22 of the socket 16.

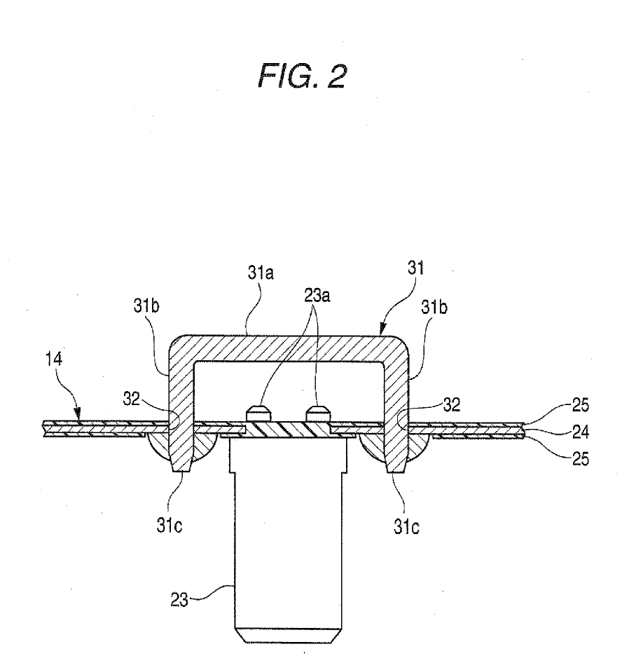

As shown in FIG. 2, the circuit board 14 has the plate-shaped metal core 24 and the insulative section 25 formed so as to cover the surface of the metal core 24. The circuit board 14 is fabricated by laminating the metal core 24 and the insulative section 25 one on another.

The metal core 24 is for example, a plate made of copper. The insulative section 25 is formed by molding glass epoxy resin, etc, having nonconductive property and low heat conductivity. In addition, instead of the copper, aluminum that specific gravity is about one third of copper may be employed as the material of the metal core 24.

On the circuit board 14 made of the metal core board, the conductive circuit pattern (not shown) made of copper foil is formed in the insulative section 25.

Further, the electrical component 23 such as relays is mounted on the circuit board 14, and then the terminal section 23a of the electrical component 23 is soldered to the circuit pattern to electrically connect with each other.

Furthermore, the radiation plate (heat radiation member) 31 is provided to the circuit board 14. The radiation plate 31 is formed by any suitable metallic material having a superior thermal conductivity, such as copper or aluminum. The radiation plate 31 is an U-shaped member in which side sections 31b are provided at both ends of a top section 31a.

The radiation plate 31 is disposed in the vicinity of the electrical component 23 facing the circuit board 14 so as to span the attaching position. Then, the radiation plate 31 is attached to the circuit board 14 in a such manner that leg section 31c formed in the attachment plate section 31b is inserted and penetrated, and attached by soldering to the exposed portion of the metal core 24 that the insulating section 25 around the edge of the through hole 32 is eliminated.

With the above configuration, heat transferred from the electrical component 23 mounted on the circuit board 14 is transferred to the metal core 24 of the circuit board 14 and then radiated from the radiation plate 31 attached to the metal core 24.

Thus, since the radiation plate 31 is connected to the metal core 24 of the circuit board 14, the heat of the electrical component 23 transferred to the metal core 24 can be surely radiated from the radiation plate 31. As a result, because the heat-conductive insulating sheet, the radiation fin or the heat pipe are not necessary, it allows supplying large current into the circuit board without using bus bar. Further, due to the simplification of the structure, it allows reduction in size and weight, and cost-saving. It also permits easy dismantlement, without limiting the attaching position. Therefore, the soaking and radiation performance, and a recycling efficiency can be much improved.

In particular, since the radiation plate 31 is provided in the vicinity of the electrical component 23, the radiation of the electrical component 23 mounted on the circuit board 14 can be effectively performed.

Next, a second embodiment of the invention will be described. Components similar to those in the first embodiment will be designated by the same reference numerals. The repetitive explanations for those will be omitted.

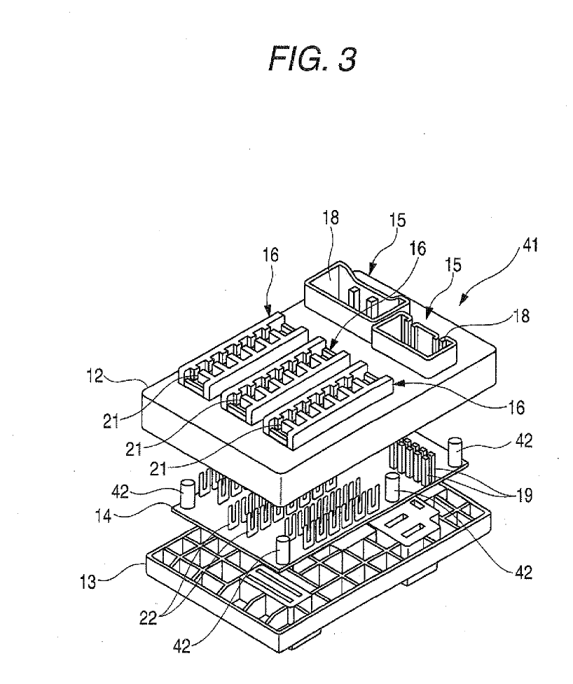

As shown in FIG. 3, an electrical connection box 41 has a plurality of sockets 15. The connector of the wiring harness side is engaged with engaging concave portion 18 of the socket 15, and then the terminal of the connector is electrically connected to the connection terminal 19 of the circuit board 14 disposed within the engaging concave portion 18.

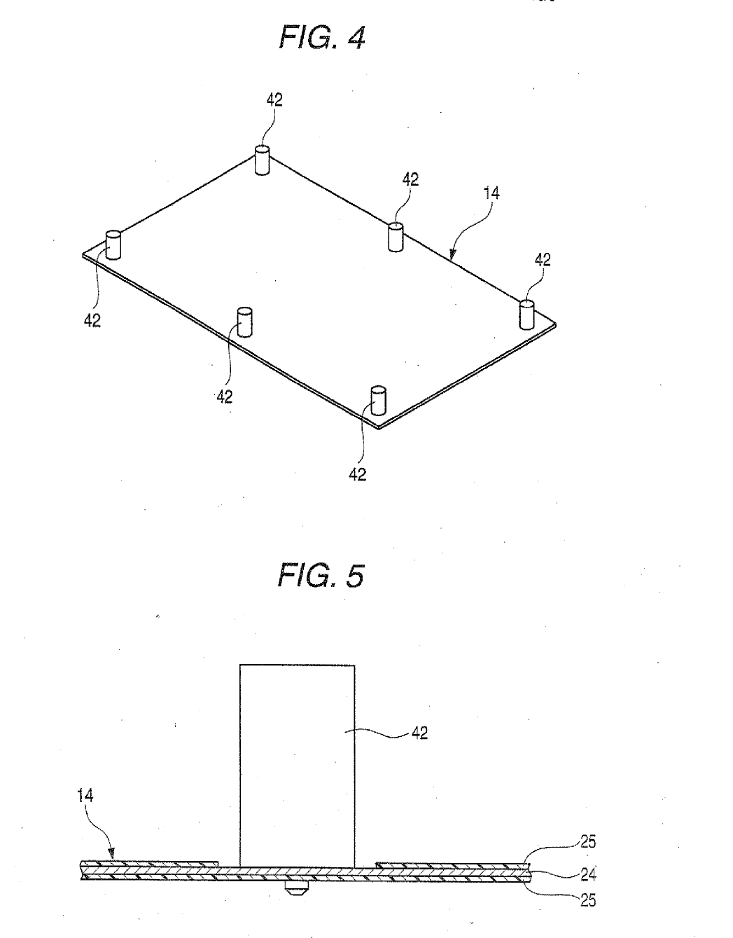

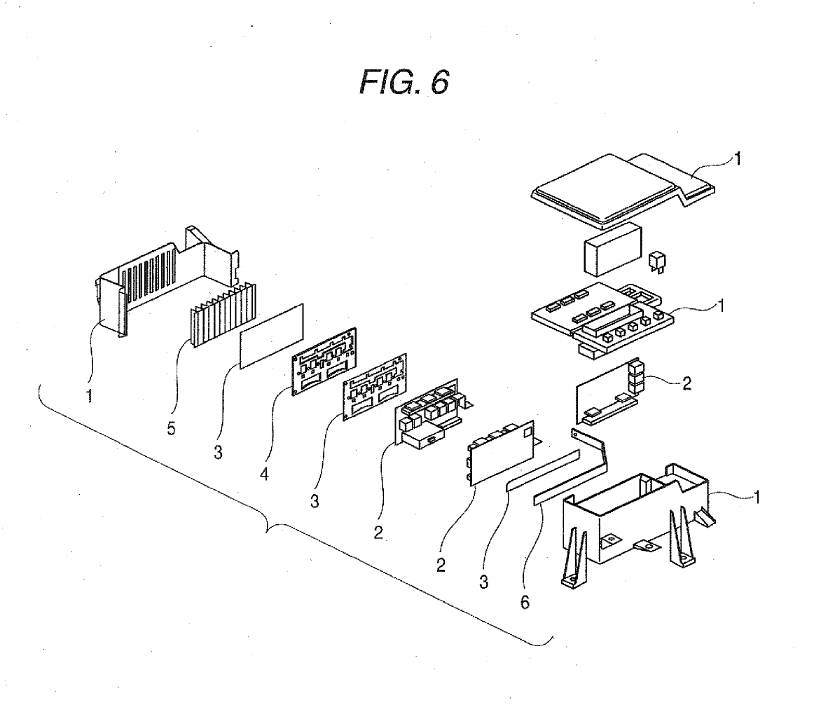

As shown in FIG. 4, in the electrical connection box 41, the radiation pins 42 having columnar shapes are arranged and spaced with each other.

The radiation pins 42 are formed with metallic material having a superior thermal conductivity, such as copper or aluminum. As shown in FIG. 5, these radiation pins 42 are attached by soldering to the exposed portion of the metal core 24 that the insulating section 25 in the circuit board 14 is eliminated.

In addition, these radiation pins 42 serve as a supporting member of the circuit board 14 with respect to the upper cover 12. The radiation pins 42 are matched with the upper cover 12, and thus the circuit board 14 is disposed in a predetermined position with respect to the upper cover 12.

In this embodiment, since the radiation pin 42 is connected to the metal core 24 of the circuit board 14, the heat of the electrical component 23 transferred to the metal core 24 can be surely radiated from the radiation pins 42. As a result, because the heat-conductive insulating sheet, the radiation fin or the heat pipe are not necessary, it allows supplying large current into the circuit board without using bus bar. Further, due to the simplification of the structure, it allows reduction in size and weight, and cost-saving. It also permits easy dismantlement, without limiting the attaching position. Therefore, the soaking and radiation performance, and a recycling efficiency can be much improved.

In particular, since the radiation pin 42 serves as a supporting member that supports he circuit board 14 with respect to the upper casing 12, as compared to a case where a separate supporting member, the number of the components can be reduced and then simpler structure can be accomplished.

Alternatively, the circuit board 14 may be fixed to the upper cover 12 in such a manner that a screw hole is formed in the radiation pin 42, a through-hole communicating with the screw hole is formed in the upper cover 12, and a beads is inserted to the through-hole to screw onto the screw hole of the radiation pin 42.

Although only some exemplary embodiments of the invention have been described in detail above those skilled in the art will readily appreciated that many modifications are possible in the exemplary embodiments without materially departing from the novel teachings and advantages of the invention. Accordingly, all such modifications are intended to be included within the scope of the invention.

The disclosure of Japanese Patent Application No. 2006-149982 filed May 30, 2006 including specification, drawings and claims is incorporated herein by reference in its entirety.

What is claimed is:

1. An electrical connection box, comprising:
a circuit board, including a plate-shaped conductive core and an insulative section covering the core;
an electrical component, disposed on the insulative section;
a heat radiating member, disposed on the insulative section and connected to the core; and
a casing, housing the circuit board, the electrical component and the heat generating member.

2. The electrical connection box as set forth in claim 1, wherein the heat radiating member is disposed in the vicinity of the electrical component.

3. The electrical connection box as set forth in claim 1, wherein the heat radiating member abuts against an inner face of the casing.
